(19) United States
(12) Patent Application Publication
(10) Pub. No.: US 2020/0351596 A1
(43) Pub. Date: Nov. 5, 2020

(54) MICROPHONE DEVICE AND METHOD FOR MANUFACTURING SAME

(71) Applicants: SHUNSIN TECHNOLOGY (ZHONG SHAN) LIMITED, Zhongshan (CN); ShunSin Technology Holdings Limited Taiwan Branch, New Taipei City (TW)

(72) Inventors: JIAN-WEN HU, Zhongshan City (CN); HONG-GUANG HUANG, Shenzhen (CN); SHUN-LONG LEE, New Taipei (TW)

(21) Appl. No.: 16/842,316

(22) Filed: Apr. 7, 2020

(30) Foreign Application Priority Data
Apr. 30, 2019 (CN) 201910364125.5

(51) Int. Cl. H04R 19/04; H04R 1/08; H05K 1/02; B81B 7/00

(52) U.S. Cl. CPC H04R 19/04; H04R 1/08; B81B 2201/0257; B81B 7/0032; H05K 1/02

(57) ABSTRACT

A MEMS microphone device greatly reduced in size includes a metallic substrate, a printed circuit including an audio sensor, and a processing chip. The metallic substrate includes a first bent portion and a second bent portion. The printed circuit is directly formed by thick film printing on the metal substrate which is then punched and shaped into the first and second bent portions. The audio sensor receives sounds and functions as a microphone. The processing chip is coupled to the printed circuit and processes the electrical signal. A method for manufacturing such microphone device is also disclosed.

### FIELD

The subject matter herein generally relates to microphone devices and manufacturing methods for the microphone device.

### BACKGROUND

Micro-electromechanical systems (MEMS) integrate various functions such as electronics, motors, or machinery into a micro-device or component. Compared with conventional electret condenser microphones (ECM) formed by assembly methods, MEMS microphones have advantages of a smaller size, lower power consumption, and higher suppression of environment interference, such as temperature changes and electromagnetic interferences.

However, conventional MEMS microphones are generally made into integrated circuits on a circuit board, and then glued to a metal shell with glue. Such manufacturing and assembly processes may be complicated and resulting the MEMS with large package sizes.

Therefore, there is room for improvement within the art.

### BRIEF DESCRIPTION OF THE DRAWINGS

Many aspects of the present disclosure are better understood with reference to the following drawings. The components in the drawings are not necessarily drawn to scale, the emphasis instead being placed upon clearly illustrating the principles of the present disclosure. It will be appreciated that for simplicity and clarity of illustration, where appropriate, reference numerals have been repeated among the different figures to indicate corresponding or analogous elements.

FIG. 1 is a cross-sectional view showing a microphone device according to an embodiment of the present disclosure.

FIG. 2 is a flowchart of a method for manufacturing a microphone device according to an embodiment of the present disclosure; and

FIGS. 3A, 3B, 3C, 3D, and 3E are cross-sectional views of a microphone device by implementing the method for manufacturing the microphone device according to FIG. 2.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one”.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

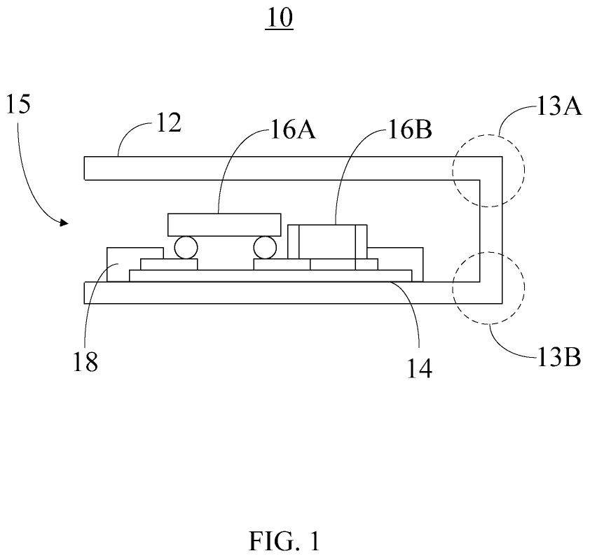

FIG. 1 illustrates a microphone device according to an embodiment of the present disclosure. The microphone device 10 according to an embodiment of the present disclosure comprises a metallic substrate 12, a printed circuit 14, electronic components 16A and 16B, and a solder mask 18. For ease of illustrating, FIG. 1 only shows a cross-section of the microphone device according to an embodiment of the present disclosure. In actual implementation, the metallic substrate 12 forms a cavity to generate a resonance effect. Such structure is wholly conventional and will be fully appreciated by those of ordinary skill in the art. The detailed structure of the metallic substrate 12 is omitted here for sake of brevity.

In FIG. 1, the metallic substrate 12 comprises a bent portion 13A and a bent portion 13B. The printed circuit 14 is formed on the metallic substrate 12. According to an embodiment of the present disclosure, the printed circuit 14 can be printed on the metallic substrate 12 by thick film print technology, that is, a screen printing method, to print ink as the material of conductors, resistors, and insulation layers on the metallic substrate 12. In an embodiment, the metallic substrate 12 can be made from aluminum, stainless steel, or other alloys. In an embodiment, the metallic substrate 12 is punched to form a bent portion 13A and a bent portion 13B, and other bent portions, and then a cavity for receiving the printed circuit 14, the electronic components 16A and 16B, and the solder mask 18 is formed. In other embodiments, a plurality of metallic substrates 12 can be combined by bonding, pasting, welding, buckling, and screw fastening to form the cavity.

The microphone device of the present disclosure utilizes the metallic substrate 12 as the housing of the microphone device. The metallic substrate 12 provides metal shielding, improves the sound quality of the microphone, and improves heat dissipation. Furthermore, in the embodiment of the present disclosure, the printed circuit 14 is directly printed on a surface of the metallic substrate 12 by thick film print technology, that is, the printed circuit 14 does not need to be first printed on a ceramic substrate and the ceramic substrate then bonded to the metallic substrate 12 with glue. Therefore, embodiments according to the present disclosure, there is no glue layer between the metallic substrate 12 and the printed circuit 14.

The electronic component 16A can be an audio sensor, which is coupled to the printed circuit 14 and receives sounds from the outside through the sound hole 15, and converts the sounds into electrical signal. According to an embodiment of the present disclosure, the audio sensor can be a microelectromechanical system (MEMS). The electronic component 16B can be a processing chip, which is coupled to the printed circuit 14 to process the electrical signals generated by the audio sensor.

According to an embodiment of the present disclosure, the processing chip can be an application-specific integrated circuit (ASIC) designed and manufactured according to specific user needs and specific electronic systems. For example, the processing chip may comprise a voltage doubler circuit, a voltage stabilization circuit, an amplifier circuit, an analog to digital converter, or a combination thereof, which has small size, improved performance, and superior noise suppression.

In addition, the electronic component 16B may also be a signal processing circuit. The signal processing circuit can be composed of capacitors, resistors, and a combination thereof, to regulate and filter the electrical signals generated by the audio sensor. According to an embodiment of the present disclosure, the audio sensor, the processing chip, and the signal processing circuit may use a flip chip packaging process to form a chip connection bump, and then the chip is flipped over to directly electrical connect the chip connection bump and the printed circuit 14. In other embodiments, the audio sensor, the processing chip, and the signal processing circuit can also be mounted on the printed circuit 14 using surface mounted technology (SMT).

The solder mask 18 covers a part of the printed circuit 14. According to an embodiment of the present disclosure, the solder mask 18 protects the copper foil (not shown) of the circuit from being oxidized and isolates the solder from affecting the functions of the circuit board. The solder mask 18 is printed to cover the parts of the metallic substrate 12 not to be soldered.

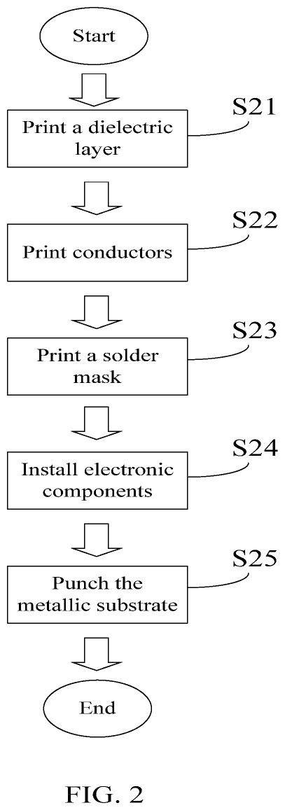

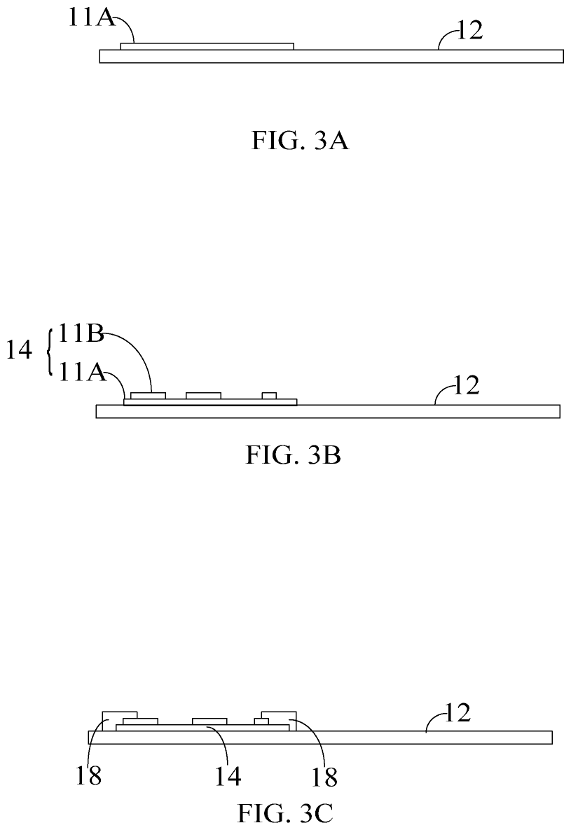

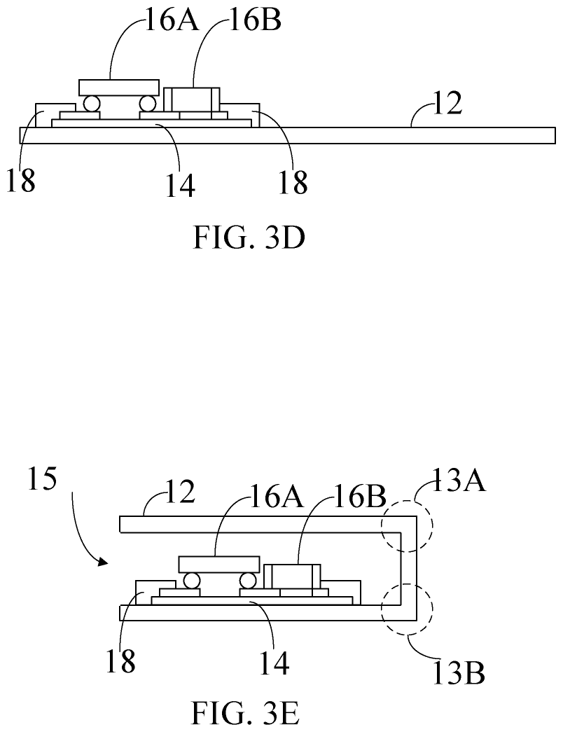

FIG. 2 illustrates the method for manufacturing a microphone device according to an embodiment of the present disclosure. FIGS. 3A-3E illustrate corresponding embodiments during implementation of the method of the present disclosure. Referring to FIG. 2 and FIG. 3A, a dielectric layer 11A is printed on the metallic substrate 12 (block S21). The dielectric layer 11A is further thermal treated, e.g. firing, sintering, and baking to form predetermined wiring lines. The layer of the wiring line can be single or multiple layers. According to an embodiment of the present disclosure, the metallic substrate 12 can be made from aluminum, stainless steel, or other alloys. The dielectric layer 11A can be an inter-metal dielectric (IMD) layer.

Next, as shown in FIG. 3B, a conductor 11B is printed on the dielectric layer 11A (block S22). The dielectric layer 11A and the conductor 11B comprise a printed circuit 14. According to an embodiment of the present disclosure, the printed circuit 14 can be printed on the metallic substrate 12 by thick film print technology, that is, a screen printing method.

Next, as shown in FIG. 3C, a solder mask 18 is formed to cover a part of the printed circuit 14 and a part of the metallic substrate 12 (block S23). According to an embodiment of the present disclosure, the solder mask 18 protects the copper foil of circuit from being oxidized and prevents contact with the solder. The solder mask 18 can be printed to cover the non-solderable parts of the metallic substrate 12.

Next, as shown in FIG. 3D, electronic components 16A and 16B are installed on the printed circuit 14 (block S24). According to an embodiment of the present disclosure, the electronic component 16A is an audio sensor. The audio sensor can be a microelectromechanical system (MEMS). The electronic component 16B is a processing chip, which processes the electrical signals generated by the audio sensor. The processing chip is an application-specific integrated circuit (ASIC), designed and manufactured according to specific user needs and specific electronic systems. For example, the processing chip may comprise a voltage doubler circuit, a voltage stabilization circuit, an amplifier circuit, an analog to digital converter, and a combination thereof. In addition, the electronic component 16B may also be a signal processing circuit, regulating and filtering the electrical signals generated by the audio sensor.

According to an embodiment of the present disclosure, the audio sensor, the processing chip, and the signal processing circuit use a flip chip packaging process to form a chip connection bump, and then the chip is flipped. In other embodiments, the audio sensor, the processing chip, and the signal processing circuit can also be mounted on the printed circuit 14 using surface mounted technology (SMT).

Next, as shown in FIG. 3E, the metallic substrate 12 is punched to form a bent portion 13A and a bent portion 13B (block S25). After punching, the electronic components 16A and 16B are located between the first bent portion and the second bent portion, and the method for manufacturing the microphone device according to one embodiment of the present disclosure is completed. Electrical terminals on the metallic substrate 12 can be electrically connected to other electronic devices. According to the embodiment of the present disclosure, the microphone device may be installed in a handheld communication device (such as a mobile phone or a smart phone), a laptop computer, a headset, a media tablet computer, a portable game instrument, a camera, a television, or a hearing aid, for example.

Implementations according to the present disclosure, the circuit is printed directly on the metallic substrate, thereby the processes of printing the circuit on a ceramic substrate and bonding the ceramic substrate to the metallic substrate with glue can be eliminated. As a result, the thickness of the microphone device may be reduced from 10 mil to less than 2 mil, greatly reducing a total volume of the microphone device. Furthermore, according to the method as disclosed in the present disclosure, processes of printing a circuit on a ceramic substrate and adhering the ceramic substrate to a metallic substrate with glue can be omitted, thereby improving the production efficiency.

Many details are often found in the relevant art, thus many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A microphone device comprising:
a metallic substrate comprising a first bent portion and a second bent portion;
a printed circuit formed on the metal substrate;
an audio sensor coupled to the printed circuit, the audio sensor receiving and converting an acoustic signal into an electrical signal; and
a processing chip coupled to the printed circuit, the processing chip processing the electrical signal.

2. The microphone device of claim 1, wherein the audio sensor and the processing chip are located between the first bent portion and the second bent portion.

3. The microphone device of claim 1, wherein the metallic substrate is made from aluminum, stainless steel, or other alloys.

4. The microphone device of claim 1, further comprising a solder mask covering a part of the printed circuit.

5. The microphone device of claim 1, wherein the processing chip comprises a voltage doubler circuit, a voltage stabilization circuit, an amplifier circuit, an analog to digital converter, or a combination thereof.

6. The microphone device of claim 1, further comprising a signal processing circuit, the signal processing circuit comprising capacitors, resistors or a combination thereof.

7. A method for manufacturing a microphone device, comprising:
providing a metallic substrate;
forming a printed circuit on the metallic substrate;
providing a plurality of electronic components on the printed circuit and coupling the plurality of electronic components to the printed circuit, the plurality of electronic components comprising an audio sensor and a processing chip, wherein the audio sensor receives and converts an acoustic signal into an electrical signal, and the processing chip processes the electrical signal; and
punching the metallic substrate to form a first bent portion and a second bent portion, wherein the plurality of electronic components are located between the first bent portion and the second bent portion.

8. The method of claim 7, wherein the metallic substrate is made from aluminum, stainless steel, or other alloys.

9. The method of claim 7, further comprising forming a solder mask to cover a part of the printed circuit.

10. The method of claim 7, wherein the processing chip comprises a voltage doubler circuit, a voltage stabilization circuit, an amplifier circuit, an analog to digital converter, or a combination thereof.
